(19) United States
(12) Patent Application Publication
(10) Pub. No.: US 2022/0189522 A1
(43) Pub. Date: Jun. 16, 2022

(54) MULTI-ACCESS MEMORY CELL

(71) Applicant: Honeywell International Inc., Charlotte, NC (US)

(72) Inventor: Robert Rabe, Chanhassen, MN (US)

(21) Appl. No.: 17/450,231

(22) Filed: Oct. 7, 2021

Related U.S. Application Data
(60) Provisional application No. 63/199,261, filed on Dec. 16, 2020.

(51) Int. Cl. G11C 8/16

(52) U.S. Cl. CPC G11C 8/16

(57) ABSTRACT

An example device includes a memory element configured to store a state for a bit in response to a write operation and to output an indication of the state for the bit in response to a read operation. The device includes first access circuitry coupled to the memory element. The first access circuitry is configured to allow a first current to flow through the first access circuitry in response to being driven in the read operation or the write operation. The device includes second access circuitry coupled to the memory element. The second access circuitry is configured to allow a second current to flow through the second access circuitry in response to being driven in the write operation. A transconductance of the first access device is different than a transconductance of the second access device.

### PRIORITY CLAIM

This application claims benefit to U.S. Provisional Application No. 63/199,261, filed Dec. 16, 2020, the entire contents of which is incorporated herein by reference.

### TECHNICAL FIELD

The disclosure relates to computer memory circuitry.

### BACKGROUND

A conventional memory cell array has access circuitry, e.g., a transistor, in each cell to select a memory element for both read operations and write operations. The access circuitry is designed to conduct a relatively large current during a write operation in order to coerce the memory element to a desired state, for example, high or low (1 or 0). During a read operation, the access circuitry may conduct a much smaller current in order to sense the state of the memory element without altering the stored state. The read operation therefore depends on sensing a small signal on a bit line. In a conventional memory array, thousands of cells are connected to the bit line and a source line.

### SUMMARY

During a write operation, access circuitry may be of sufficient size and transconductance (gm) to conduct the minimum current needed to impose the desired state on the memory element during the write operation. However, as access circuitry transconductance is increased, leakage current also may increase when the access circuitry is in the ‘off’ or non-accessed state. The combined leakage current of many unselected ‘off’ access circuits leaking onto the bit line may interfere with a computing device sensing the small intended signal developed on the bit line by a selected (or “on”) cell during the read operation.

Additionally, data throughput of a memory array may be limited by the rate at which the memory cells can be accessed. A single-access memory cell or single-access array typically permits only one cell to be accessed per operation and typically does not permit simultaneous operations.

In general, this disclosure describes an example device for storing a bit. The device includes first access circuitry and second access circuitry. Both the first access circuitry and the second access circuitry are coupled to a memory element. The first access circuitry has a first transconductance configured to allow a first current to flow through the first access circuitry electrically coupling the memory element to a first bit line in response to being driven in the read operation or the write operation. The second access circuitry has a second transconductance that is different from the first transconductance (e.g., larger than the first transconductance) and is configured to allow a second current to flow through the second access circuitry electrically coupling the memory element to a second bit line in response to being driven in the write operation, but not in the read operation. In this manner, leakage current may be less likely to interfere with a read operation. Additionally, a read operation may be conducted at the same time as a write operation to different memory cells which may improve memory access times when compared to memory cells using only a single access circuitry with a single transconductance.

In one example of the disclosure, a device for storing a bit includes a memory element being configured to store a state for the bit in response to a write operation and to output an indication of the state for the bit in response to a read operation, first access circuitry coupled to the memory element, the first access circuitry having a first transconductance, and being configured to allow a first current to flow through the first access circuitry electrically coupling the memory element to a first bit line in response to being driven in the read operation or the write operation, second access circuitry coupled to the memory element, the second access circuitry having a second transconductance, the second transconductance being different than first transconductance, and the second access circuitry being configured to allow a second current to flow through the second access circuitry electrically coupling the memory element to a second bit line in response to being driven in the write operation and refrain from allowing the second current to flow in the read operation.

In another example, a memory device includes a first bit line, a second bit line, a source line and an array of memory cells coupled to the first bit line, the second bit line, and the source line, wherein each of the memory cells of the array of memory cells includes: a memory element being configured to store a state for a bit in response to the write operation and to output an indication of the state for the bit in response to the read operation; first access circuitry coupled to the first bit line, the memory element, the first access circuitry having a first transconductance, and being configured to allow a first current to flow through the first access circuitry electrically coupling the memory element to the first bit line in response to being driven in the read operation or the write operation; and second access circuitry coupled to the second bit line, and the memory element, the second access circuitry having a second transconductance, the second transconductance being different than the first transconductance, and the second access circuitry being configured to allow a second current to flow through the second access circuitry electrically coupling the memory element to the second bit line in response to being driven in the write operation and refrain from allowing the second current to flow through the second access circuitry in the read operation.

In another example, a method of operating a memory device includes: applying, by a computing device, a first voltage to a first access circuitry; gaining access, by the computing device and in response to the application of the first voltage, to a first bit stored in a memory element through the first access circuitry, the first access circuitry being coupled to the memory element; reading, by the computing device, the bit stored in the memory element through a first bit line, the first bit line being coupled to the first access circuitry; applying, by the computing device, a second voltage to a second access circuitry; applying, by the computing device, a third voltage representing a second bit to a second bit line; gaining access, by the computing device, to the memory element through the second access circuitry, the second access circuitry being coupled to the memory element; writing, by the computing device, the second bit to the memory element, wherein the first access circuitry has a first transconductance and the second access circuitry has a second transconductance and the first transconductance is different than the second transconductance.

The details of one or more examples of the disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 is a conceptual diagram illustrating an example of a single-access memory cell.

FIG. 2 is a conceptual diagram illustrating an example of a single-access memory array.

FIG. 3 is a conceptual diagram illustrating an example multiple-access memory cell according to the techniques of this disclosure.

FIG. 4 is a conceptual diagram illustrating an example of a single fingered transistor and examples of multi-fingered transistors.

FIG. 5 is a conceptual diagram illustrating an example multiple-access memory device according to the techniques of this disclosure.

FIG. 6 is a conceptual diagram illustrating an example positive multiple-access memory cell and an example negative multiple access memory cell according to the techniques of this disclosure.

FIG. 7 is a conceptual diagram illustrating an example differential multiple-access memory device according to the techniques of this disclosure.

FIG. 8 is a block diagram of an example computing device and a multi-access memory device according to the techniques of this disclosure.

FIG. 9 is a flow chart illustrating an example operation of a multiple-access memory device according to one or more techniques of this disclosure.

### DETAILED DESCRIPTION

A computing device write operation to a memory element (e.g., random access memory (RAM), magnetic RAM (MRAM), programmable read access memory (P-ROM) or the like) typically uses more current than a read operation. The access circuitry used to access a memory element of a memory cell may be of sufficient device size and transconductance (gm) to conduct the minimum current needed to impose the desired state (e.g., write a bit) on the memory element during the write operation. However, as the access circuitry transconductance is increased, leakage current may increase when the access circuitry is in the ‘off’ or non-accessed state (e.g., when a computing device is not attempting to access a memory element through the access circuitry). For example, when access circuitry is in the off state, although unintended, a small amount of current may actually flow through the access circuitry. This small amount of current is leakage current. This leakage current may create a problem during the read operation. For example, many unaccessed ‘off’ access circuitries may leak current onto the bit line. The combined leakage current may interfere with a computing device sensing the small intended signal developed on the bit line by a selected, “on”, or currently accessed memory cell during the read operation. For example, a computing device may erroneously read a bit as high or 1 when the actual stored bit is a low or 0. Additionally, with a traditional memory array, only one operation may be conducted at a given time.

According to the techniques of this disclosure, an example device for storing a bit is described. The device includes first access circuitry and second access circuitry. Both the first access circuitry and the second access circuitry are coupled to a memory element. For example, the first access circuitry may include a first transconductance which may be selected to minimize or reduce a leakage current on a first bit line. The second access circuitry may include a second transconductance which may be selected to maximize or increase an amount of current during a write operation on a second bit line. In this manner, read operations and write operations may be performed more reliably and write operations performed faster.

The first transconductance may be configured to allow a first current to flow through the first access circuitry electrically coupling the memory element to a first bit line in response to being driven in the read operation or the write operation. The second transconductance, which is different than the first transconductance, may be configured to allow a second current to flow through the second access circuitry electrically coupling the memory element to a second bit line in response to being driven in the write operation, but not in the read operation. In this manner, leakage current may be less likely to interfere with a read operation and a write operation may be performed more quickly. Additionally, a read operation may be conducted at the same time as a write operation on separate bit lines.

For example, the second transconductance may be higher than the first transconductance. By using a separate bit line for read operations through the first access circuitry with lower transconductance than the transconductance of the second device, the collective leakage current on that separate bit line may be lower than in a single-access memory array and therefore less likely to interfere with the reading of the stored bit.

In some examples, both the first access circuitry and the second access circuitry may be on during a write operation. As used herein, when access circuitry is activated or on, a bit line is electrically coupled to a memory cell through the access circuitry that is activated or on. For example, when the access circuitry is activated or on, a channel exists between a source and a drain of the access circuitry. For example, when access circuitry is activated or on, a computing device may be attempting to perform a read or a write operation through that access circuitry. When access circuitry is off, the access circuitry is not activated. While some leakage current may flow, a bit line is not intended to be electrically coupled to a memory cell through the access circuitry that is not activated or off. For example, a computing device may not be performing a read or a write operation through the access circuitry. In some examples, only the second access circuitry may be on during a write operation.

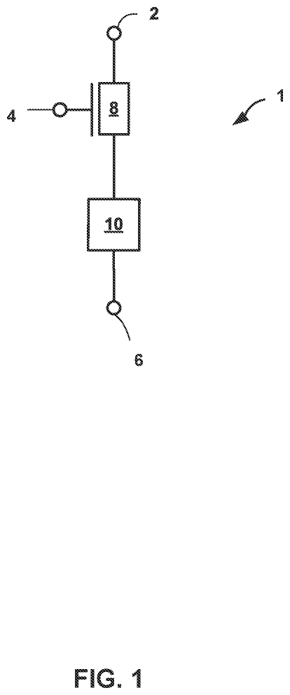

FIG. 1 is a conceptual diagram illustrating an example of a single-access memory cell. A single-access memory cell 1 includes a bit line connection 2 for connecting to a bit line, an access connection 4 for connecting to an access line, and a source line connection 6 for connecting to a source voltage. For example, a source voltage may be a voltage applied to a source of a transistor. The access line is used to access memory cell 1 during a read operation or a write operation. The bit line is used to write a value (e.g., 1 or 0) to the memory cell or read a value from the memory cell. Single-access memory cell 1 of FIG. 1 also includes access circuitry 8 and a memory element 10. Some examples of access circuitry may include, but are not limited to, a silicon-controlled rectifier (SCR), a Field Effect Transistor (FET), and a bipolar junction transistor (BJT). Examples of FETs may include, but are not limited to, a junction field-effect transistor (JFET), a metal-oxide-semiconductor FET (MOSFET), a dual-gate MOSFET, an insulated-gate bipolar transistor (IGBT), any other type of FET, or any combination of the same. Examples of MOSFETS may include, but are not limited to, a depletion mode p-channel MOSFET (PMOS), an enhancement mode PMOS, depletion mode n-channel MOSFET (NMOS), an enhancement mode NMOS, a double-diffused MOSFET (DMOS), any other type of MOSFET, or any combination of the same. Examples of BJTs may include, but are not limited to, PNP, NPN, heterojunction, or any other type of BJT, or any combination of the same. It should be understood that access circuitry may be high-side or low-side access circuitry. Additionally, access circuitry may be voltage-controlled and/or current-controlled. Examples of current-controlled access circuitry may include, but are not limited to, gallium nitride (GaN) MOSFETs, BJTs, or other current-controlled elements. Some examples of memory elements may include random access memory (RAM), magnetic RAM (MRAM), dynamic RAM (DRAM), synchronous DRAM (SDRAM), double data rate (DDR) RAM, programmable read only memory (PROM) or any other volatile or non-volatile memory element.

Access circuitry 8 provides access to memory element 10 based on a voltage being applied to access connection 4. For example, when a high voltage is applied to access connection 4, access circuitry 8 may switch or turn on, thereby electrically coupling bit line connection 2 to memory element 10. When a low voltage is applied to access connection 4, access circuitry 8 may switch or turn off, thereby effectively decoupling bit line connection 2 from memory element 10. In some examples, access circuitry 8 may be a transistor and access connection 4 may be coupled to the base of the transistor or be the base of the transistor. Memory element 10 stores a bit. In the case of a binary memory, memory element 10 may store a 0 or 1 (e.g., a low or high voltage). In some cases, the memory cell may not be binary, but may be configured to hold one of more than two states.

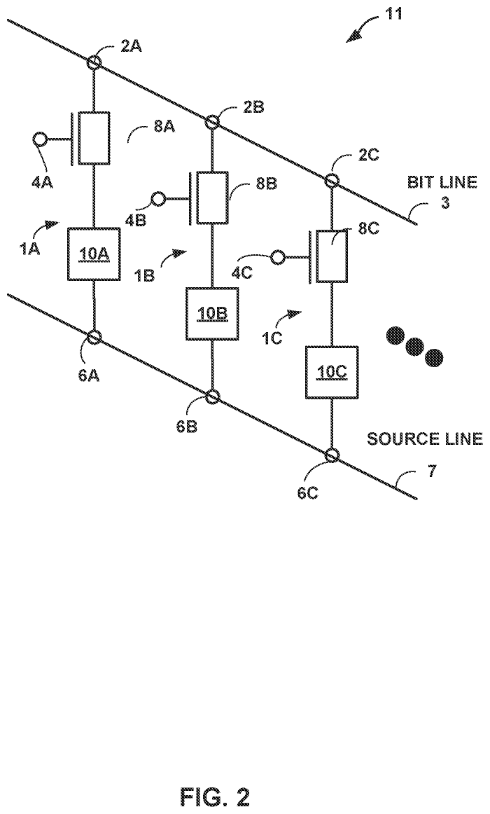

FIG. 2 is a conceptual diagram illustrating an example of a single-access memory array. In the example of FIG. 2, three memory cells of memory device 11 arm shown. Each of the memory cells of FIG. 2 may be an example of the memory cell of FIG. 1. Each of the memory cells includes a bit line connection coupled to bit line 3. Each of the memory cells includes a source connection coupled to source line 7. A first memory cell 1A includes access circuitry 8A that is coupled to bit line connection 2A and has an access connection 4A. First memory cell 1A also includes a memory element 10A coupled to source line connection 6A and access circuitry 8A. A second memory cell 1B includes access circuitry 8B that is coupled to bit line connection 2B and has an access connection 4B. Second memory cell 1B also includes a memory element 10B coupled to source line connection 6B and access circuitry 8B. A third memory cell 1C includes access circuitry 8C that is coupled to bit line connection 2C and has an access connection 4C. Third memory cell 1C also includes a memory element 10C coupled to source line connection 6C and access circuitry 8C. Memory array 11 may include numerous more memory cells which are indicated by the three dots in FIG. 2.

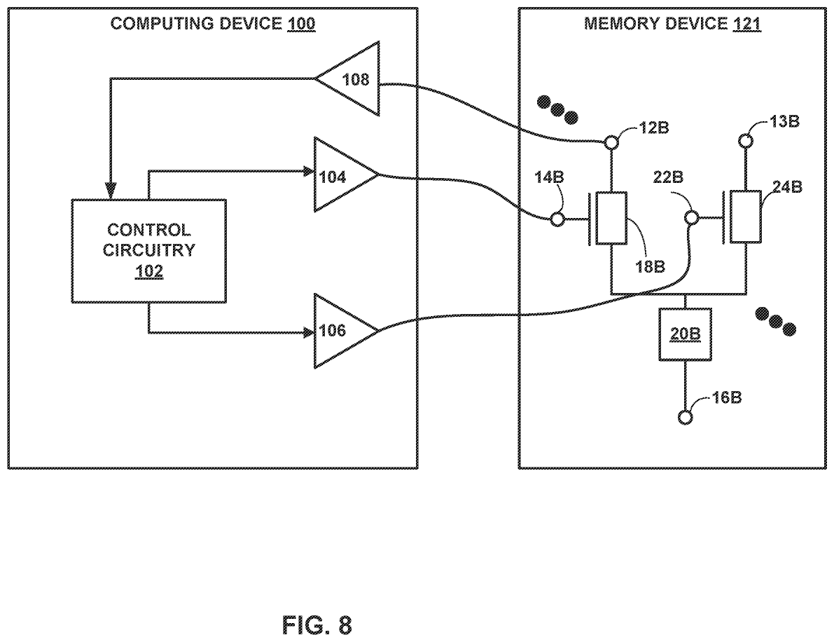

For example, during a write operation to second memory cell 1B of memory array 11, a computing device (e.g., computing device 100 of FIG. 8) may apply the bit to be written to memory element 10B, in the form of a voltage, to bit line 3. The computing device may also apply a voltage to access connection 4B to select the memory element 10B into which to write the bit. By applying the voltage to access connection 4B, the computing device activates or turns on access circuitry 4B (e.g., generates a channel between a source and a drain of access circuitry 4B) allowing current to flow through access circuitry 4B. Access circuitry 4B thereby provides access to memory element 10B to the bit on bit line 3. In this manner, the bit is written into memory element 10B. During a read operation from second memory cell 1B, for example, the computing device applies a voltage to access connection 4B to select the memory element 10B from which to read the bit on bit line 3. Access circuitry 8B provides access to memory element 10B to bit line 3. The voltage representing the bit in memory element 10B is applied to bit line 3 through access circuitry 8B. The computing device (e.g., computing device 100 of FIG. 8) may then read the bit from bit line 3. In this manner, the bit is read from memory element 10B. However, as there may be a large number of memory cells in memory array 11, leakage from memory element 10A, memory element 10C and many other memory elements that may be part of memory array 11 may create noise on bit line 3 that may interfere with the ability of the computing device to accurately read the bit in memory element 10B.

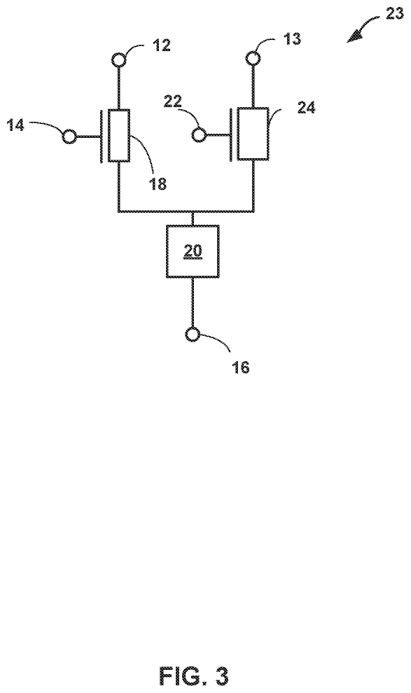

FIG. 3 is a conceptual diagram illustrating an example multiple-access memory cell 23 according to the techniques of this disclosure. In the example of FIG. 3, an example multi-access memory cell contains multiple access circuitries, e.g., first access circuitry 18 and second access circuitry 24. First access circuitry 18 may have a first access connection 14. Second access circuitry 24 may have a second access connection 22. First access circuitry 18 is coupled to first bit line connection 12. Second access circuitry 24 is coupled to second bit line connection 13. In some examples, first access circuitry 18 may be a transistor and first access connection 14 may be coupled to a gate of first access circuitry 18 or may be the gate of first access circuitry 18. In some examples, second access circuitry 24 may be a transistor and second access connection 22 may be coupled to a gate of second access circuitry 24 or may be the gate of second access circuitry 24. Both first access circuitry 18 and second access circuitry 24 may be coupled to memory element 20. Memory element 20 may be coupled to a source line connection 16. Memory element 20 may be configured to store a bit.

First access circuitry 18 may be configured to provide access to memory element 20 to first bit line through first bit line connection 12. Second access circuitry 24 may be configured to provide access to memory element 20 to second bit line through second bit line connection 13. In some examples, first access circuitry 18 may include a p-channel transistor and second access circuitry 24 may include an n-channel transistor. In some examples, first access circuitry 18 may include an n-channel transistor and second access circuitry 24 may include a p-channel transistor. In some examples, first access circuitry 18 may include an n-channel transistor and second access circuitry 24 may include an n-channel transistor. In some examples, first access circuitry 18 may include a p-channel transistor and second access circuitry 24 may include a p-channel transistor.

For example, a device for storing a bit may include memory element 20 configured to store a state for the bit in response to a write operation and to output an indication of the state for the bit in response to a read operation. The device may include first access circuitry 18 coupled to memory element 20, first access circuitry 18 having a first transconductance, and being configured to allow a first current to flow through first access circuitry 18 to memory element 20 in response to being driven in the read operation or the write operation. The device may further include second access circuitry 24 coupled to memory element 20, second access circuitry 24 having a second transconductance, the second transconductance being different than first transconductance, and second access circuitry 24 being configured to allow a second current to flow through second access circuitry 24 to memory element 20 in response to being driven in the write operation and refrain from allowing the second current to flow in the read operation.

In some examples, first access circuitry 18 may be configured to have a smaller leakage current and/or a smaller transconductance (gm) than second access circuitry 24. For example, first access circuitry 18 may have a first transconductance and second access circuitry 24 may have a second transconductance. The second transconductance may be higher than the first transconductance. For example, the first transconductance may be configured to provide for a smaller leakage current and the second transconductance may be configured to provide for faster writing operations.

There are a number of different ways in which to implement the difference in transconductance (or leakage current) between the first access device and the second access device. In some examples, the second transconductance is different than the first transconductance based on first access circuitry 18 having a smaller device width (e.g., first access circuitry may be narrower) than a device width of second access circuitry 24.

In some examples, the second transconductance is different than the first transconductance based on first access circuitry 18 having a longer device length (e.g., first access circuitry 18 is longer) than a device length of second access circuitry 24. In some examples, the second transconductance is different than the first transconductance based on first access circuitry 18 having a larger threshold voltage than second access circuitry 24. In some examples, the second transconductance is different than the first transconductance based on first access circuitry 18 having a lower electron mobility than second access circuitry 24. Electron mobility is the speed at which an electron can move through a semiconductor. A lower electron mobility means the electron moves more slowly through the semiconductor, thereby resulting in a lower current through the semiconductor compared to semiconductors with higher electron mobility.

In some examples, the second transconductance is different than the first transconductance based on second access circuitry 24 having a thicker gate oxide layer than a gate oxide layer of first access circuitry 18. For example, a gate oxide layer may be a dielectric layer that separates a gate of a transistor from a source and a drain of the transistor and separates the gate from the channel that is formed between the source and the drain while the transistor is on.

In some examples, first access circuitry 18 may be coupled to a first bit line through first bit line connection 12 and be configured to provide access for a computing device to memory element 20 during a read operation. In some examples, second access circuitry 24 may be coupled to a second bit line through second bit line connection 13 and be configured to provide access for a computing device to memory element 20 during a write operation. By providing second access circuitry 24 to provide access to the computing device during the write operation, first access circuitry 18 may be configured to have a lower leakage current in the ‘off’ state than a conventional memory cell with a single access circuitry. During a read operation, the sum of the “off” leakage currents of the many non-selected first access circuitries on the first bit line may generate less leakage and interference than in a conventional memory array. Also, by providing second access circuitry 24 to provide access to the computing device during the write operation, second access circuitry 24 may be configured with additional transconductance over a single-access circuit, if desired, to optimize the write operation. Further, although second access circuitry 24 may be configured to conduct the current for the write operation, a computing device may use both first access circuitry 18 and second access circuitry 24 in combination during a write operation which may allow an overall size of a multiple-access memory device according to the techniques of this disclosure to approach the overall size of a conventional single-access memory array as the size of second access circuitry 24 may be reduced in such cases.

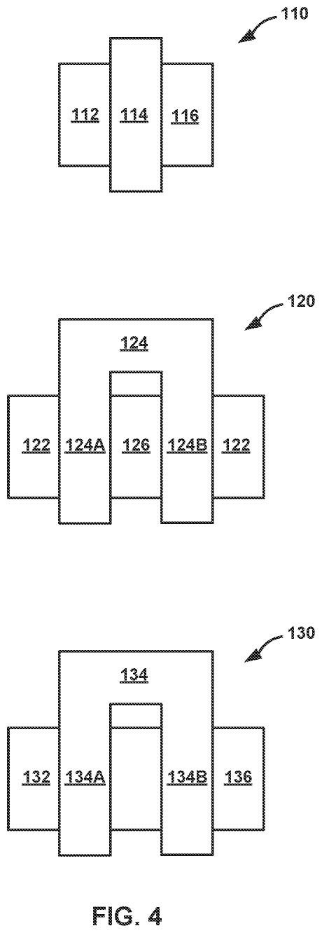

FIG. 4 is a conceptual diagram illustrating an example of a single fingered transistor and examples of multi-fingered transistors. Some transistors may have gates with multiple “fingers”. Multi-fingered transistors have gates that include more than one physical stripe of material (e.g., two or more stripes of gate material separated from each other), thus multiple fingers. For example, transistor 110 is an example single fingered transistor. Transistor 110 includes source 112, gate 114 and drain 116. Transistor 110 is a single-fingered transistor as the gate 114 is a single physical stripe of material. Transistor 120 is an example of a multi-fingered transistor. Transistor 120 includes source 122, gate 124 and drain 126. Gate 124 includes finger 124A and finger 124B. As can be seen, two stripes of gate material are separated by drain 126. Transistor 130 is another example of a multi-fingered transistor. Transistor 130 includes source 132, gate 134 and drain 136. Gate 134 includes finger 134A and finger 134B. As can be seen, transistor 130 also includes two stripes of gate material.

In some examples, the second transconductance is different than the first transconductance based on first access circuitry 18 including a first transistor with a different number of fingers than a second transistor of second access circuitry 24. For example, the second transconductance is different than the first transconductance based on first access circuitry 18 including a first transistor including at least one finger and second access circuitry 24 including a second transistor having a gate including at least two fingers, where the gate of the first transistor includes fewer fingers than the gate of the second transistor.

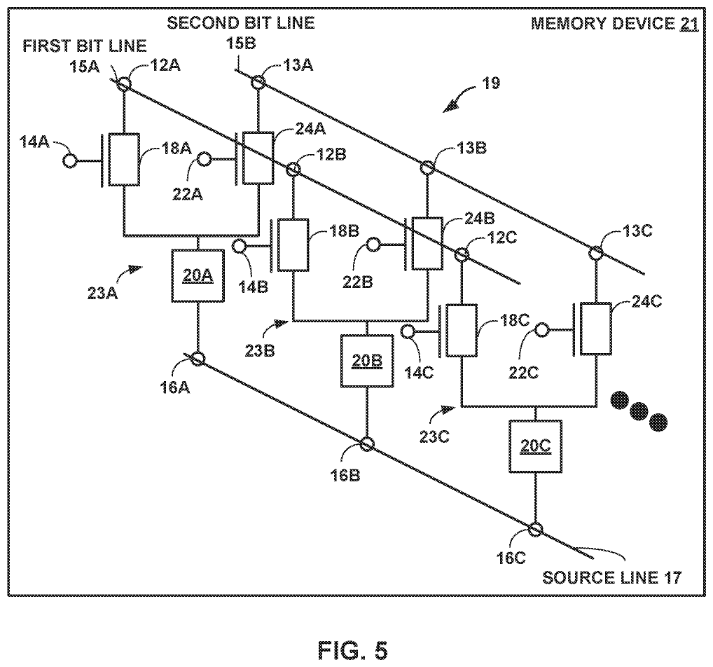

FIG. 5 is a conceptual diagram illustrating an example multiple-access memory device according to the techniques of this disclosure. In the example of FIG. 5, memory device 21 includes a memory array 19. Three memory cells of memory device 21 are shown. Each of the memory cells of FIG. 5 may be an example of the memory cell of FIG. 3. Each of the memory cells of memory array 19 includes a first bit line connection coupled to first bit line 15A. Each of the memory cells of memory array 19 also includes a second bit line connection coupled to second bit line 15B. Each of the memory cells of memory array 19 includes a source connection coupled to source line 17.

A first memory cell 23A includes first access circuitry 18A that is coupled to first bit line connection 12A and has a first access connection 14A. First memory cell 23A includes second access circuitry 24A that is coupled to second bit line connection 13A and has a second access connection 22A. First memory cell 23A also includes a memory element 20A coupled to source line connection 16A, to first access circuitry 18A, and to second access circuitry 24A.

A second memory cell 23B includes first access circuitry 18B that is coupled to first bit line connection 12B and has a first access connection 14B. Second memory cell 23B includes a second access circuitry 24B that is coupled to second bit line connection 13B and has a second access connection 22B. Second memory cell 23B also includes a memory element 20B coupled to source line connection 16B, to first access circuitry 18B, and to second access circuitry 24B.

A third memory cell 23C includes first access circuitry 18C that is coupled to first bit line connection 12C and has a first access connection 14C. Third memory cell 23C includes second access circuitry 24C that is coupled to second bit line connection 13C and has a second access connection 22C. Third memory cell 23C also includes a memory element 20C coupled to source line connection 16C, to first access circuitry 18C, and to second access circuitry 24C. Memory device 21 may include numerous more memory cells which are indicated by the three dots in FIG. 5.

For example, memory device 21 may include a first bit line 15A, a second bit line 15B and a source line 17. Memory device 21 may also include an array of memory cells (e.g., memory array 19) coupled to first bit line 15A, second bit line 15B, and source line 17. Each of the memory cells of the array of memory cells (e.g., memory array 19) may include a memory element (e.g., memory element 20A) configured to store a state for a bit in response to a write operation and to output an indication of the state for the bit in response to a read operation. Each of the memory cells of the array of memory cells (e.g., memory array 19) may include first access circuitry (e.g., first access circuitry 18A) coupled to first bit line 15A, the memory element, the first access circuitry having a first transconductance, and being configured to allow a first current to flow through the first access circuitry electrically coupling the memory element to a first bit line in response to being driven in the read operation or the write operation. Each of the memory cells of the array of memory cells (e.g., memory array 19) may also include second access circuitry (e.g., second access circuitry 24A) coupled to second bit line 15B and the memory element. The second access circuitry may have a second transconductance and the second transconductance may be different than the first transconductance. The second access circuitry may be configured to allow a second current to flow through the second access circuitry electrically coupling the memory element to a second bit line in response to being driven in the write operation and refrain from allowing the second current to flow through the second access circuitry to the memory element in the read operation.

For example, during a write operation to second memory cell 23B, a computing device (e.g., computing device 100 of FIG. 8) applies the bit intended to be written to memory element 20B, in the form of a voltage, to second bit line 15B, which, in some examples, may be referred to as a write bit line. The computing device also applies a voltage to second access connection 22B to select the memory element 20B into which to write the bit. By applying the voltage to second access connection 22B, computing device turns on second access circuitry 24B allowing current to flow through second access circuitry 24B. Second access circuitry 24B thereby provides access to the bit to memory element 20B through second bit line 15B and second bit line connection 13B. In this manner, the bit is written into memory element 20B. While the write operation is described above using second bit line 15B, in some examples the computing device may perform a write operation using first bit line 15A or second bit line 15B or both first bit line 15A and second bit line 15B (in which case the operation described above and the operation described immediately below may be done simultaneously or substantially simultaneously).

When a computing device (e.g., computing device 100 of FIG. 8) performs a write operation to second memory cell 23B using first bit line 15A, the computing device applies the bit intended to be written to memory element 20B, in the form of a voltage, to first bit line 15A, which, in this example, may be referred to as a read/write bit line. The computing device also applies a voltage to first access connection 14B to select the memory element 20B into which to write the bit. By applying the voltage to first access connection 14B, computing device turns on first access circuitry 18B allowing current to flow through first access circuitry 18B. First access circuitry 18B thereby provides access to memory element 20B to the bit on first bit line 15A through first bit line connection 12B. In this manner, the bit is written into memory element 20B.

During a read operation from second memory cell 23B, for example, the computing device (e.g., computing device 100 of FIG. 8) applies a voltage to first access connection 14B to select the memory element 20B from which to read the bit. By applying the voltage to first access connection 14B, computing device turns on first access circuitry 18B allowing current to flow through first access circuitry 18B. First access circuitry 18B provides access to memory element 20B to first bit line 15A, which, in some examples, may be referred to as a read bit line or a read/write bit line. The voltage representing the bit in memory element 20B is applied to first bit line 15A through first access circuitry 18B. The computing device may then read the bit from first bit line 15A. In this manner, the computing device reads the bit from memory element 20B.

According to the techniques of this disclosure, more than one memory cell may be accessed simultaneously. For example, with one first access circuitry (e.g., first access circuitry 18B) and one second access circuitry (second access circuitry 24A), a read operation and write operation (as described above) may be conducted at the same time (e.g., simultaneously or overlapping in time) on two different cells. In this example, the computing device may read the bit stored in memory element 20B while writing a bit to memory element 20A.

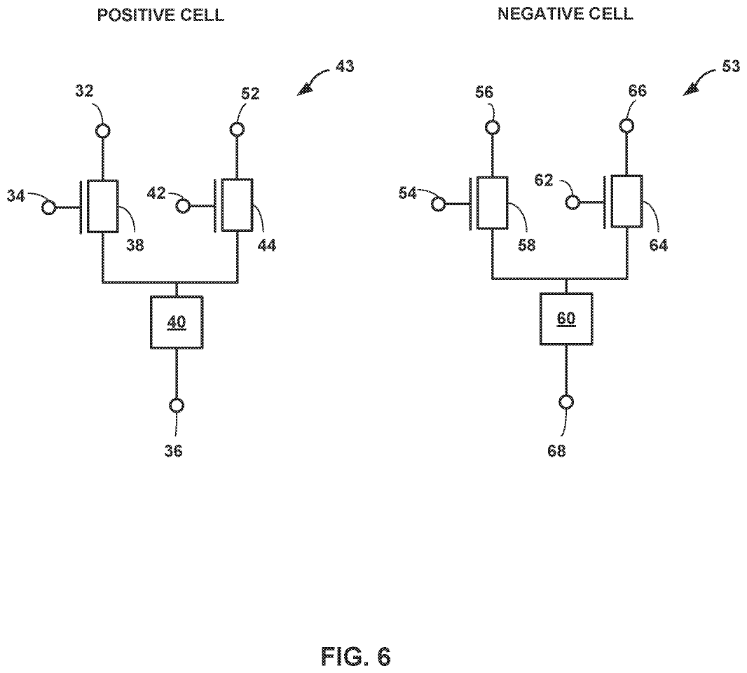

FIG. 6 is a conceptual diagram illustrating an example positive multiple-access memory cell 43 and an example negative multiple access memory cell 53 according to the techniques of this disclosure. The differential form of a multi-access cell operates similarly to the example non-differential multi-access memory cell of FIG. 3. In the case of the differential multi-access cell, a positive instance of each cell operates as described for the non-differential version, and a duplicate negative instance of each cell is operated using the same access signals (e.g., signals applied to the first access connections or the second access connections), but using the opposite data state on the bit line. For example, if a positive cell stores a high or 1, the corresponding negative cell will store a low or 0. The positive and negative cell instances for a given data bit may be accessed simultaneously (or near simultaneously) during a write operation to store opposite data states. The positive and negative cell instances may also be accessed simultaneously (or near simultaneously) during a read operation to generate opposite signal excursions on a first positive bit line and a first negative bit line at a sense amplifier. In some examples, a device may sense both the differential signal and the two individual single-ended (positive and negative) signals.

In the example of FIG. 6, the benefits of having first access circuitry and second access circuitry with different transconductances and/or current leakage apply as described previously for the example of FIG. 3. The differential version may occupy more area per stored data bit, but may also provide about double the differential read signal amplitude at the sense amplifier and thereby may further mitigate the effect of common-mode noise components (e.g., current leakage) during a read operation.

In the example of FIG. 6, positive memory cell 43 includes first positive access circuitry 34 and second positive access circuitry 42. First access circuitry 38 has a first positive access connection 34. Second positive access circuitry 44 has a second positive access connection 42. First positive access circuitry 38 is coupled to a first positive bit line connection 32. Second positive access circuitry 44 is coupled to a second positive bit line connection 52. In some examples, first positive access circuitry 38 may include a transistor and first positive access connection 34 may be coupled to a gate of first positive access circuitry 38 or may be the gate of first positive access circuitry 38. In some examples, second positive access circuitry 44 may be a transistor and second positive access connection 42 may be coupled to a gate of second positive access circuitry 44 or may be the gate of second positive access circuitry 44. Both first positive access circuitry 38 and second positive access circuitry 44 may be coupled to positive memory element 40. Positive memory element 40 may be coupled to a positive source line connection 36. Positive memory element 40 may be configured to store a bit.

First positive access circuitry 38 may be configured to provide access to positive memory element 40 to a first positive bit line through first positive bit line connection 32. Second positive access circuitry 44 may be configured to provide access to a second positive bit line through second positive bit line connection 52.

Similarly, negative memory cell 53 includes first negative access circuitry 58 and second negative access circuitry 64. First negative access circuitry 58 has a first negative access connection 54. Second negative access circuitry 64 has a second negative access connection 62. First negative access circuitry 58 is coupled to a first negative bit line connection 56. Second negative access circuitry 64 is coupled to a second negative bit line connection 66. In some examples, first negative access circuitry 58 may be a transistor and first negative access connection 54 may be coupled to a gate of first negative access circuitry 58 or may be the gate of first negative access circuitry 58. In some examples, second negative access circuitry 64 may be a transistor and second negative access connection 62 may be coupled to a gate of second negative access circuitry 64 or may be the gate of second negative access circuitry 64. Both first negative access circuitry 58 and second negative access circuitry 64 may be coupled to negative memory element 60. Negative memory element 60 may be coupled to a negative source line connection 68. Negative memory element 60 may be configured to store a bit in an opposite state of that of a corresponding positive memory element 40 when the positive memory cell and the negative memory cell are paired. For example, if positive memory element 40 stores a 1, negative memory element 60 stores a 0. If positive memory element 40 stores a 0, negative memory element 60 stores a 1.

First negative access circuitry 58 may be configured to provide access to negative memory element 60 to a first negative bit line through first negative bit line connection 56. Second negative access circuitry 64 may be configured to provide access to a second negative bit line through second negative bit line connection 66.

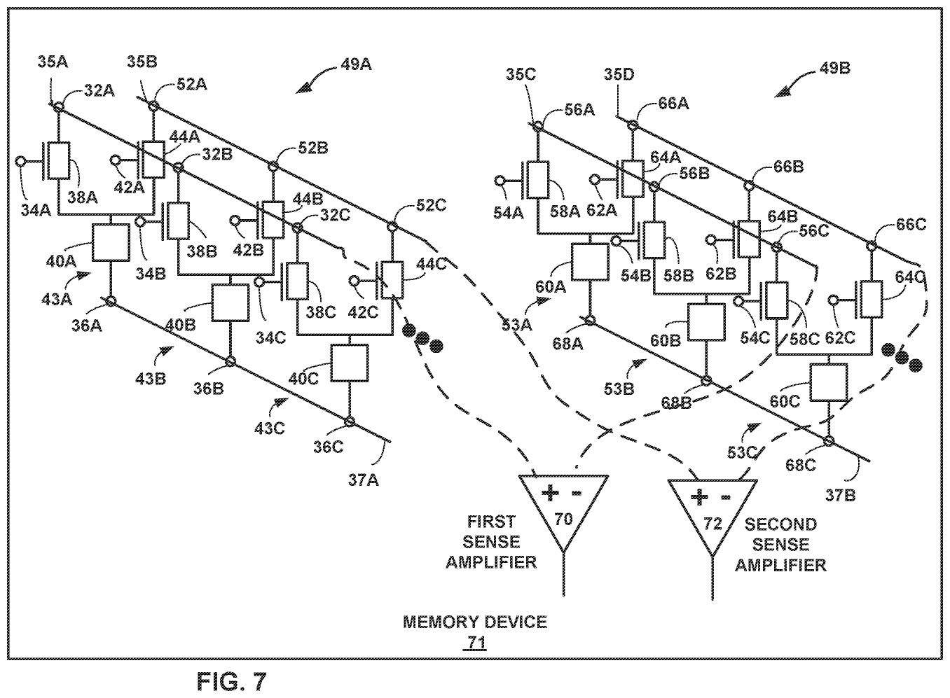

FIG. 7 is a conceptual diagram illustrating an example differential multiple-access memory device 71 according to the techniques of this disclosure. In the example of FIG. 7, a positive memory array 49A and a negative memory array 49B are shown. Three positive memory cells of positive memory array 49A and three negative memory cells of negative memory array 49B are shown. Each of the positive memory cells of FIG. 7 may be an example of the positive memory cell of FIG. 6 and each of the negative memory cells of FIG. 7 may be an example of the negative memory cell of FIG. 6.

Each of the positive memory cells of positive memory array 49A includes a first positive bit line connection coupled to first positive bit line 35A. Each of the positive memory cells of positive memory array 49A also includes a second positive bit line connection coupled to second positive bit line 35B. Each of the positive memory cells of positive memory array 49A includes a positive source connection coupled to positive source line 37A. A first positive memory cell 43A includes first positive access circuitry 38A that is coupled to first positive bit line connection 32A and has a first positive access connection 34A. First positive memory cell 43A includes second positive access circuitry 44A that is coupled to second positive bit line connection 52A and has a second positive access connection 42A. First positive memory cell 43A also includes a positive memory element 40A coupled to positive source line connection 36A, to first positive access circuitry 38A, and to second positive access circuitry 44A. A second positive memory cell 43B includes first positive access circuitry 38B that is coupled to first positive bit line connection 32B and has a first positive access connection 34B. Second positive memory cell 43B includes second positive access circuitry 44B that is coupled to second positive bit line connection 52B and has a second positive access connection 42B. Second positive memory cell 43B also includes a positive memory element 40B coupled to positive source line connection 36B, to first positive access circuitry 38B, and to second positive access circuitry 44B. A third positive memory cell 43C includes first positive access circuitry 38C that is coupled to first positive bit line connection 32C and has a first positive access connection 34C. Third positive memory cell 43C includes second positive access circuitry 44C that is coupled to second positive bit line connection 52C and has a second positive access connection 42C. Third positive memory cell 43C also includes a positive memory element 40C coupled to positive source line connection 36C, to first positive access circuitry 38C, and to second positive access circuitry 44C. Memory device 71 may include numerous more positive memory cells which are indicated by the three dots on the left of FIG. 7.

Memory device 71 also includes a number of negative memory cells. Each of the negative memory cells of negative memory array 49B includes a first negative bit line connection coupled to first negative bit line 35C. Each of the negative memory cells of negative memory array 49B also includes a second negative bit line connection coupled to second negative bit line 35D. Each of the negative memory cells of negative memory array 49B includes a negative source connection coupled to negative source line N 37B. A first negative memory cell 53A includes first negative access circuitry 58A that is coupled to first negative bit line connection 56A and has a first negative access connection 54A. First negative memory cell 53A includes second negative access circuitry 64A that is coupled to second negative bit line connection 66A and has a second negative access connection 62A. First negative memory cell 53A also includes a negative memory element 60A coupled to negative source line connection 68A, to first negative access circuitry 58A, and to second negative access circuitry 64A. A second negative memory cell 53B includes first negative access circuitry 58B that is coupled to first negative bit line connection 56B and has a first negative access connection 54B. Second negative memory cell 53B includes second negative access circuitry 64B that is coupled to second negative bit line connection 66B and has a second negative access connection 62B. Second negative memory cell 53B also includes a negative memory element 60B coupled to negative source line connection 68B, to first negative access circuitry 58B, and to second negative access circuitry 64B. A third negative memory cell 53C includes first negative access circuitry 58C that is coupled to first negative bit line connection 56C and has a first negative access connection 54C. Third negative memory cell 53C includes second negative access circuitry 64C that is coupled to second negative bit line connection 66C and has a second negative access connection 62C. Third negative memory cell 53C also includes a negative memory element 60C coupled to negative source line connection 68C, to first negative access circuitry 58C, and to second negative access circuitry 64C. Memory device 71 may include numerous more negative memory cells which are indicated by the three dots on the right of FIG. 7.

First positive bit line 35A may be coupled to a positive input to a sense amplifier 70. First negative bit line 35C may be coupled to a negative (or inverting) input to sense amplifier 70.

For example, during a write operation to second positive memory cell 43B and corresponding second negative memory cell 53B, a computing device (e.g., computing device 100 of FIG. 8) may apply the bit intended to be written to positive memory element 40B, in the form of a voltage, to second positive bit line 35B, which, in some examples, may be referred to as a write bit line. The computing device may also apply the bit intended to be written to negative memory element 60B, in the form of a voltage representing the opposite state of the bit intended to be written to positive memory element 40B, to second negative bit line 35D.

The computing device also applies a voltage to second positive access connection 42B and to second negative access connection 62B to select positive memory element 40B and negative memory element 60B, respectively, into which to write the bit. By applying the voltage to second positive access connection 42B, computing device turns on second positive access circuitry 44B allowing current to flow through second positive access circuitry 44B. Similarly, by applying the voltage to second negative access connection 62B, computing device turns on second negative access circuitry 64B allowing current to flow through second negative access circuitry 64B. Second positive access circuitry 44B thereby provides access to positive memory element 40B to the bit on second positive bit line 35B through second positive bit line connection 52B and second negative access circuitry 64B provides access to negative memory element 60B to the bit (opposite of that on second positive bit line 35B) on second negative bit line 35D through second negative bit line connection 66B. In this manner, the bit is written into positive memory element 40B and negative memory element 60B (in the opposite state of that of the bit in memory written into positive memory element 40B). While the write operation is described above using second positive bit line 15B and second negative bit line 35D, in some examples the computing device may perform a write operation using: 1) first positive bit line 35A and first negative bit line 35C; 2) second positive bit line 35B and second negative bit line 35D; or 3) first positive bit line 35A, first negative bit line 35C, second positive bit line 35B and second negative bit line 35D (in which case the operation described above and the operation described immediately below may be done simultaneously or substantially simultaneously).

In some examples, memory device 71 may include first positive bit line 35A, second positive bit line 35B, and positive source line 37A. Memory device 71 may also include a positive array of memory cells coupled to first positive bit line 35A, second positive bit line 35B, and positive source line 37A. Each of the positive memory cells of positive memory array 49A may include a positive memory element (e.g., positive memory element 40A) being configured to store a state for a bit in response to the write operation and to output an indication of the state for the bit in response to the read operation. Each of the positive memory cells of positive memory array 49A may also include first positive access circuitry (e.g., first positive access circuitry 38A) coupled to first positive bit line 35A and the positive memory element (e.g., positive memory element 40A).

The first positive access circuitry may have a first transconductance and be configured to allow a first current to flow through the first positive access circuitry (e.g., first positive access circuitry 38A) electrically coupling the positive memory element (e.g., positive memory element 40A) to first positive bit line 35A in response to being driven in the read operation or the write operation. Each memory cell may also include second positive access circuitry (e.g., second positive access circuitry 44A) coupled to second positive bit line 35B and the positive memory element (e.g., positive memory element 40A). The second positive access circuitry may have a second transconductance. The second transconductance may be different than the first transconductance. The second positive access circuitry may be configured to allow a second current to flow through the second positive access circuitry electrically coupling the positive memory element to second positive bit line 35B in response to being driven in the write operation and refrain from allowing the second current to flow through the second positive access circuitry in the read operation.

In some examples, memory device 71 may include first negative bit line 35C, second negative bit line 35D, and negative source line 37B. Memory device 71 may also include a sense amplifier 70 coupled to first positive bit line 35A and first negative bit line 35C. Memory device 71 may also include a negative array of memory cells coupled to first negative bit line 35C, second negative bit line 35D, and negative source line 37B. Each of the negative memory cells of negative memory array 49B may include a negative memory element (e.g., memory element 60A) being configured to store a state for a bit in response to the write operation and to output an indication of the state for the bit in response to the read operation. Each of the negative memory cells of negative memory array 49B may also include a first negative access circuitry (e.g., first negative access circuitry 58A) coupled to first negative bit line 35C and the negative memory element (e.g., negative memory element 60A).

The first negative access circuitry may have the first transconductance and be configured to allow a third current to flow through the first negative access circuitry (e.g., first negative access circuitry 58A) electrically coupling the negative memory element (e.g., negative memory element 60A) to negative bit line 35C in response to being driven in the read operation or the write operation. Each negative memory cell of negative memory array 49B may also include second negative access circuitry (e.g., second negative access circuitry 64A) coupled to second negative bit line 35D and the negative memory element (e.g., negative memory element 60A). The second negative access circuitry may have the second transconductance and the second negative access circuitry may be configured to allow a fourth current to flow through the second negative access circuitry (e.g., second negative access circuitry 64A) electrically coupling the negative memory element (e.g., negative memory element 60A) to second negative bit line 35D in response to being driven in the write operation and refrain from allowing the fourth current to flow through the second negative access circuitry in the read operation. The positive memory element (e.g., positive memory element 40A) stores a bit in an opposite state than a corresponding negative memory element (e.g., negative memory element 60A).

For example, during a write operation to the second positive and corresponding second negative memory cell, a computing device may apply the bit intended to be written to positive memory element 40B, in the form of a voltage, to first positive bit line 35A, which, in some examples, may be referred to as a read/write bit line. The computing device may also apply the bit intended to be written to negative memory element 60B, in the form of a voltage representing the opposite state of the bit intended to be written to positive memory element 40B, to first negative bit line 35C.

The computing device also applies a voltage to first positive access connection 34B and to first negative access connection 54B to select the positive memory element 40B and negative memory element 60B, respectively, into which to write the bit. By applying the voltage to first positive access connection 34B, computing device turns on first positive access circuitry 38B allowing current to flow through first positive access circuitry 34B. Similarly, by applying the voltage to first negative access connection 54B, computing device turns on first negative access circuitry 58B allowing current to flow through first negative access circuitry 58B. First positive access circuitry 38B thereby provides access to positive memory element 40B to the bit on first positive bit line 35A through first positive bit line connection 32B and first negative access circuitry 58B provides access to negative memory element 60B to the bit (opposite of that on first positive bit line 35A) on first negative bit line 35C through first negative bit line connection 56B. In this manner, the bit is written into positive memory element 40B and negative memory element 60B (in the opposite state of that of the bit in memory written into positive memory element 40B).

During a read operation from the second positive memory cell and corresponding second negative memory cell, for example, the computing device applies a voltage to first positive access connection 34B and to first negative access connection 54B to select the positive memory element 40B and negative memory element 60B, respectively, from which to read the bit. By applying the voltage to first positive access connection 34B, the computing device turns on first positive access circuitry 38B allowing current to flow through first positive access circuitry 38B. Similarly, by applying the voltage to first negative access connection 54B, the computing device turns on first negative access circuitry 58B allowing current to flow through first negative access circuitry 58B. First positive access circuitry 38B provides access to positive memory element 40B to first positive bit line 35A, which, in some examples, may be referred to as a positive read bit line, through first positive bit line connection 32B. First negative access circuitry 58B provides access to negative memory element 60B to first negative bit line 35C, which, in some examples, may be referred to as a negative read bit line, through first negative bit line connection 56B. The voltage representing the bit in positive memory element 40B is applied to first positive bit line 35A through first positive access circuitry 38B. The voltage representing the bit in negative memory element 60B (which is the opposite state of the voltage representing the bit in positive memory element 40B) is applied to first negative bit line 35C. The voltage on first positive bit line 35A is applied to a positive input of sense amplifier 70 and the voltage on first negative bit line 35C is applied to a negative input of sense amplifier 70. The computing device may read the bit from the output of sense amplifier 70. For example, positive bit line 35A may output a high or 1 and negative bit line 35C may output a low or 0. Sense amplifier 70 may then output a high or 1. As mentioned above, a differential multi-access arrangement, such as that of the example of FIG. 6, may provide about double the differential read signal amplitude at the sense amplifier and thereby may further mitigate the effect of common-mode noise components (e.g., current leakage) during a read operation.

FIG. 8 is a block diagram of an example computing device and a multi-access memory device according to the techniques of this disclosure. Memory device 121 may include a multi-access memory array or a differential multi-access memory array. Computing device 100 may include processor circuitry 102, first driver circuitry 104 and second driver circuitry 106. In some examples, first driver circuitry 104 and/or second driver circuitry 106 may be part of memory device 121 rather than computing device 100. In some examples, first driver circuitry 104 and second driver circuitry are different circuitries. In some examples, first driver circuitry 104 and second driver circuitry are one circuitry. In some examples, memory device 121 may be part of computing device 100. Processor circuitry 102 may include one or more microprocessors, graphics processing unit, general purpose graphics processing unit, display processor, memory controller, fixed circuitry or other circuitry capable of performing the functions attributed to processor circuitry 102 as described herein. For example, processor circuitry may include one or more processors, including one or more microprocessors, digital signal processors (DSPs), application specific integrated circuits (ASICs), field programmable gate arrays (FPGAs), or any other equivalent integrated or discrete logic circuitry, as well as any combinations of such components. The term “processor” or “processing circuitry” may generally refer to any of the foregoing logic circuitry, alone or in combination with other logic circuitry, or any other equivalent circuitry. In some examples, processor circuitry 102 may be a combination of one or more analog components and one or more digital components.

Processor circuitry 102 may be coupled to first driver circuitry 104 and second driver circuitry 106. First driver circuitry may be coupled to first access connection 14B in memory device 121. Second driver circuitry 106 may be coupled to second access connection 22B.

Processor circuitry 102 may provide a signal to first driver circuitry 104 when processor circuitry 102 is performing a read operation (or in some examples, a write operation) of memory element 20B. In some examples, first access circuitry 18B may be a first transistor having a first gate. First driver circuitry 104 may be configured to generate a first voltage at the first gate through first access connection 14B in response to the read operation (or in some examples, a write operation). In the examples where first access circuitry 18B is a first transistor, the first transistor may be configured to activate (e.g., turn on or create a channel between a source and a drain) in response to the first voltage at the first gate to electrically couple a first bit line (not shown for simplicity purposes) which may be coupled to first bit line connection 12B to memory element 20B, thereby enabling processor circuitry 102 to read the first bit from memory element 20B through the first bit line.

In some examples, second access circuitry 24B may be a second transistor having a second gate. Processor circuitry 102 may send a signal to second driver circuitry 106 when processor circuitry 102 is performing a write operation. Second driver circuitry 106 may be configured to generate a second voltage at the second gate through second access connection 22B in response to a write operation (but not a read operation). In the examples where second access element 24B is a second transistor, the second transistor may be configured to activate (e.g., turn on or create a channel between a source and a drain) in response to the second voltage at the second gate to electrically couple a second bit line (not shown for simplicity purposes) to memory element 20B. In this example, the second bit line is different than the first bit line.

In some examples, the first voltage may be lower than the second voltage. In other examples, the first voltage may correspond to the second voltage. For example, the first voltage may be the same as the second voltage or be approximately equal to the second voltage. For example, the circuitry may allow for independent control of the first and second voltages such that the first voltage and the second voltage may be the same or different, depending on the application need.

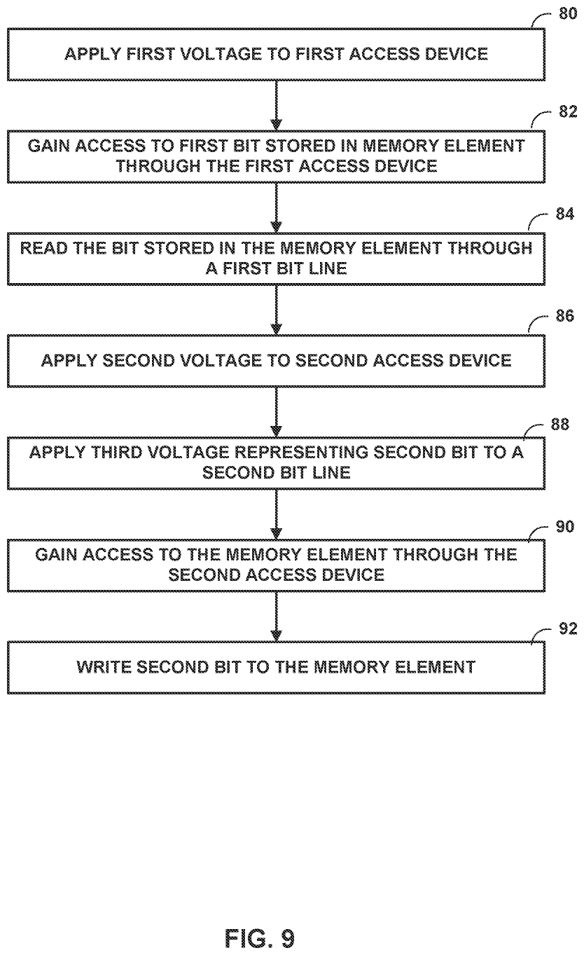

FIG. 9 is a flow chart illustrating an example operation of a multiple-access memory device according to one or more techniques of this disclosure. First driver circuitry 104 may apply a first voltage to first access circuitry (80). For example, first driver circuitry 104 may apply a first voltage through first access connection 14B to first access circuitry 18B to activate first access circuitry 18B. Computing device 100 may gain access, in response to the application of the first voltage, to a first bit stored in a memory element through the first access circuitry (82). For example, first access circuitry 18B may be coupled to memory element 20B and computing device 100 may gain access to the first bit stored in memory element 20B by causing a current to flow through first access circuitry 18B because of the application of the first voltage to first access connection 14B.

Computing device 100 may read the bit stored in the memory element through a first bit line (84). For example, first bit line 15A may be coupled to first access circuitry 18B and computing device 100 may read the bit stored in memory element 20B through first bit line 15A. Computing device 100 may apply a second voltage to a second access circuitry (86). For example, computing device 100 may apply the second voltage through second access connection 22B to second access circuitry 24B to activate second access circuitry 24B.

Computing device 100 may apply a third voltage representing a second bit to a second bit line (88). For example, computing device 100 may place a bit on second bit line 15B by applying the third voltage to second bit line 15B. Computing device 100 may gain access to the memory element through the second access circuitry (90). For example, second access circuitry 24B may be coupled to memory element 20B and computing device 100 may gain access to memory element 20B by causing a current to flow through second access circuitry 24B because of the application of the second voltage to second access connection 22B.

Computing device 100 may write the second bit to the memory element (92). For example, computing device 100 may write the second bit to memory element 20B through second bit line 15B, second bit line connection 13B and second access circuitry 24B. The first access circuitry may have a first transconductance and the second access circuitry may have a second transconductance. The first transconductance may be different than the second transconductance.

According to the techniques of this disclosure, a memory device may include a plurality of memory cells and each memory cell may include first access circuitry and second access circuitry. The first access circuitry may have a different transconductance or leakage current then the second access circuitry. The use of the first access circuitry during a read operation and not the second access circuitry may improve the ability of a computing device to accurately read a bit stored in the memory cell when compared to a conventional memory cell. Furthermore, a read operation and a write operation may be conducted at the same time with different memory cells, thereby improving memory access times.

Various examples of the disclosure have been described. These and other examples are within the scope of the following claims.

What is claimed is:

1. A device for storing a bit comprising:
a memory element being configured to store a state for the bit in response to a write operation and to output an indication of the state for the bit in response to a read operation;
first access circuitry coupled to the memory element, the first access circuitry having a first transconductance, and being configured to allow a first current to flow through the first access circuitry electrically coupling the memory element to a first bit line in response to being driven in the read operation or the write operation;
second access circuitry coupled to the memory element, the second access circuitry having a second transconductance, the second transconductance being different than first transconductance, and the second access circuitry being configured to allow a second current to flow through the second access circuitry electrically coupling the memory element to a second bit line in response to being driven in the write operation and refrain from allowing the second current to flow in the read operation.

2. The device of claim 1, wherein the second transconductance is different than the first transconductance based on the first access circuitry having a device width that is smaller than a device width of the second access circuitry.

3. The device of claim 1, wherein the second transconductance is different than the first transconductance based on the first access circuitry comprising a first transistor having a gate comprising at least one finger and the second access circuitry comprising a second transistor having a gate comprising at least two fingers, wherein the gate of the first transistor comprises fewer fingers than the gate of the second transistor.

4. The device of claim 1, wherein the second transconductance is different than the first transconductance based on the first access circuitry having a device length that is longer than a device length of the second access circuitry.

5. The device of claim 1, wherein the second transconductance is different than the first transconductance based on the first access circuitry having a lower electron mobility than an electron mobility of the second access circuitry.

6. The device of claim 1, wherein the second transconductance is different than the first transconductance based on the second access circuitry comprising a thicker gate oxide layer than a gate oxide layer of the first access circuitry.

7. The device of claim 1, wherein the second transconductance is higher than the first transconductance.

8. The device of claim 1, wherein the first access circuitry comprises a first transistor having a first gate and the second access circuitry comprises a second transistor having a second gate, the device further comprising:
a first driver circuitry coupled to the first gate, the first driver circuitry being configured to generate a first voltage at the first gate in response to the read operation or the write operation, wherein the first transistor is configured to activate in response to the first voltage at the first gate to electrically couple the first bit line to the memory element; and
a second driver circuitry coupled to the second gate, the second driver circuitry being configured to generate a second voltage at the second gate in response to the write operation, wherein the second transistor is configured to activate in response to the second voltage at the second gate to electrically couple the second bit line to the memory element, the second bit line being different than the first bit line.

9. The device of claim 8, wherein the first voltage is lower than the second voltage.

10. The device of claim 8, wherein the first voltage corresponds to the second voltage.

11. A memory device comprising:
a first bit line;
a second bit line;
a source line; and
an array of memory cells coupled to the first bit line, the second bit line, and the source line, wherein each of the memory cells of the array of memory cells comprises:
a memory element being configured to store a state for a bit in response to the write operation and to output an indication of the state for the bit in response to the read operation;
first access circuitry coupled to the first bit line, the memory element, the first access circuitry having a first transconductance, and being configured to allow a first current to flow through the first access circuitry electrically coupling the memory element to the first bit line in response to being driven in the read operation or the write operation; and
second access circuitry coupled to the second bit line, and the memory element, the second access circuitry having a second transconductance, the second transconductance being different than the first transconductance, and the second access circuitry being configured to allow a second current to flow through the second access circuitry electrically coupling the memory element to the second bit line in response to being driven in the write operation and refrain from allowing the second current to flow through the second access circuitry in the read operation.

12. The memory device of claim 11, wherein the second transconductance is different than the first transconductance based on the first access circuitry of each of the memory cells of the array of memory cells having a device width that is smaller than a device width of the second access circuitry of each of the memory cells.

12. The memory device of claim 11, wherein the second transconductance is different than the first transconductance based on the first access circuitry of each of the memory cells of the array of memory cells comprising a first transistor having a gate comprising at least two fingers and the second access circuitry of each of the memory cells of the array of memory cells comprising a second transistor having a gate comprising at least one finger, wherein the gate of the first transistor comprises more fingers than the gate of the second transistor.

13. The memory device of claim 11, wherein the second transconductance is different than the first transconductance based on the first access circuitry of each of the memory cells of the array of memory cells having a device length that is longer than a device length of the second access circuitry of each of the memory cells of the array of memory cells.

14. The memory device of claim 11, wherein the second transconductance is different than the first transconductance based on the first access circuitry of each of the memory cells of the array of memory cells having a lower electron mobility than an electron mobility of the second access circuitry of each of the memory cells of the array of memory cells.

15. The memory device of claim 11, wherein the second transconductance is different than the first transconductance based on the second access circuitry of each of the memory cells of the array of memory cells comprising a thicker oxide layer than the first access circuitry of each of the memory cells of the array of memory cells.

16. The memory device of claim 11, wherein the second access circuitry of each of the memory cells of the array of memory cells has a higher transconductance than the first access circuitry of each of the memory cells of the array of memory cells.

17. The memory device of claim 11, wherein the first access circuitry of each of the memory cells of the array of memory cells comprises a first transistor having a first gate and the second access circuitry of each of the memory cells of the array of memory cells comprises a second transistor having a second gate, the memory device further comprising:
a first driver circuitry coupled to the first gate of at least one of the first transistors, the first driver circuit being configured to generate a first voltage at the first gate of the at least one of the first transistors in response to the read operation or the write operation, wherein the at least one of the first transistors is configured to activate in response to the first voltage at the first gate of the at least one of the first transistors to electrically couple a first bit line to at least one of the memory elements; and
a second driver circuitry coupled to the second gate of at least one of the second transistors, the second driver circuitry being configured to generate a second voltage at the second gate of the at least one of the second transistors in response to the write operation, wherein the at least one of the second transistors is configured to activate in response to the second voltage at the second gate of the at least one of the second transistors to electrically couple a second bit line to at least one of the memory elements, the second bit line being different than the first bit line.

18. The memory device of claim 17, wherein the first voltage is lower than the second voltage.

19. The memory device of claim 10, wherein the array of memory cells is a positive array of memory cells, the source line is a positive source line, the memory cells are positive memory cells, the memory element is a positive memory element, the first access circuitry is first positive access circuitry, the second access circuitry is second positive access circuitry, the first bit line is a first positive bit line, and the second bit line is a second positive bit line, the memory device further comprising:
a first negative bit line;
a second negative bit line;
a negative source line;
a sense amplifier coupled to the first positive bit line and the first negative bit line; and
a negative array of memory cells coupled to the first negative bit line, the second negative bit line, and the negative source line, wherein each of the negative memory cells of the negative array of memory cells comprises:
a negative memory element being configured to store a state for a bit in response to the write operation and to output an indication of the state for the bit in response to the read operation,
first negative access circuitry coupled to the first negative bit line and the negative memory element, the first negative access circuitry having the first transconductance, and being configured to allow a third current to flow through the first negative access circuitry electrically coupling the negative memory element to the first negative bit line in response to being driven in the read operation or the write operation;
second negative access circuitry coupled to the second negative bit line and the negative memory element, the second negative access circuitry comprising the second transconductance, and the second negative access circuitry being configured to allow a fourth current to flow through the second negative access circuitry electrically coupling the negative memory element to the second negative bit line in response to being driven in the write operation and refrain from allowing the fourth current to flow through the second negative access circuitry in the read operation,
wherein the positive memory element stores a bit in an opposite state than a corresponding negative memory element.

20. A method of operating a memory device comprising:
applying, by a computing device, a first voltage to a first access circuitry;
gaining access, by the computing device and in response to the application of the first voltage, to a first bit stored in a memory element through the first access circuitry, the first access circuitry being coupled to the memory element;
reading, by the computing device, the bit stored in the memory element through a first bit line, the first bit line being coupled to the first access circuitry;
applying, by the computing device, a second voltage to a second access circuitry;
applying, by the computing device, a third voltage representing a second bit to a second bit line;
gaining access, by the computing device, to the memory element through the second access circuitry, the second access circuitry being coupled to the memory element;
writing, by the computing device, the second bit to the memory element,
wherein the first access circuitry has a first transconductance and the second access circuitry has a second transconductance and the first transconductance is different than the second transconductance.
